(19) United States
(12) Patent Application Publication
(10) Pub. No.: US 2026/0150755 A1
(43) Pub. Date: May 28, 2026

(54) STACKED DIE ELECTRONIC DEVICE WITH INTEGRATED MAGNETICS

(71) Applicant: Texas Instruments Incorporated, Dallas, TX (US)

(72) Inventors: Anindya Poddar, SUNNYVALE, CA (US); Masamitsu Matsuura, BEPPU-SHI OITA-KEN (JP); Patrick Thompson, ALLEN, TX (US); Kashyap Mohan, Irving, TX (US); Hiroyuki Sada, BEPPU-SHI OITA-KEN (JP)

(21) Appl. No.: 18/962,883

(22) Filed: Nov. 27, 2024

(51) Int. Cl. H01L 25/065; H01L 21/308; H01L 21/48; H01L 21/56; H01L 23/00; H01L 23/31; H01L 23/498; H01L 23/522; H05K 1/18

(52) U.S. Cl. CPC H10W 90/00; H05K 1/181; H10P 50/691; H10W 20/497; H10W 70/095; H10W 70/65; H10W 20/496; H10W 72/536; H10W 72/5363; H10W 72/823; H10W 72/859; H10W 72/865; H10W 72/877; H10W 72/884; H10W 74/016; H10W 74/10; H10W 74/111; H10W 74/15; H10W 90/20; H10W 90/724; H10W 90/732; H10W 90/754; H10W 90/756; H10W 90/796

(57) ABSTRACT

An electronic device includes a first semiconductor die, having a first terminal and a first metallization structure with a first coil, and a second semiconductor die, having opposite first and second sides, a second terminal, a second coil in a second metallization structure, and a dielectric layer on the second side of the second semiconductor die, with the first semiconductor die attached to the dielectric layer of the second semiconductor die, and the second coil aligned to the first coil.

### BACKGROUND

Power modules and communications devices may have circuits that operate in different voltage domains connected to separate supply voltages. Device designs can include multiple chip modules (MCMs) having multiple dies with dedicated wafer fabrications process nodes having unique isolation dielectrics and components to provide an isolation barrier between different voltage domains. However, these MCM devices typically require custom lead frame designs to provide isolated split die attach pads that increase device dimensions and add cost. Silicon on insulator (SOI) devices allow a monolithic isolation but are typically restricted to lower isolation voltage ratings and are typically capacitive and unsuited for power transfer across an isolation barrier. Another monolithic isolation approach uses backside silicon trenches filled with dielectric to form isolation barriers, which is also limited to lower isolation voltage ratings and adds wafer processing cost. Capacitive isolation approaches require extremely tight tolerances for die assembly make this complicated and expensive to manufacture.

### SUMMARY

In one aspect, an electronic device includes a first semiconductor die, having a first terminal and a first metallization structure with a first coil, as well as a second semiconductor die having opposite first and second sides, a second terminal, a second coil in a second metallization structure, and a dielectric layer on the second side of the second semiconductor die, where the first semiconductor die attached to the dielectric layer of the second semiconductor die, and the second coil aligned to the first coil.

In another aspect, a system includes a circuit board having first and second conductive features, as well as an electronic device. The electronic device has first and second semiconductor dies, the first semiconductor die having a first terminal coupled to the first conductive feature of the circuit board, and a first metallization structure with a first coil, the second semiconductor die having opposite first and second sides, a second terminal coupled to the second conductive feature of the circuit board, a second coil in a second metallization structure, and a dielectric layer on the second side of the second semiconductor die, where the first semiconductor die attached to the dielectric layer of the second semiconductor die, and the second coil aligned to the first coil.

In a further aspect, a method of fabricating an electronic device includes attaching a first semiconductor die to a second side of a second semiconductor die with a first coil of the first semiconductor die aligned with a second coil of the second semiconductor die, attaching an opposite first side of the second semiconductor die to a lead frame, electrically coupling a first terminal of the first semiconductor die to a first lead of the lead frame, and electrically coupling a second terminal of the second semiconductor die to a second lead of the lead frame.

### BRIEF DESCRIPTION OF THE DRAWINGS

FIG. 1 is a sectional side elevation view of an electronic device with stacked first and second dies with aligned respective first and second coils.

FIG. 2 is a flow diagram of a first example method of fabricating an electronic device.

FIG. 2A is a flow diagram of another example method of fabricating an electronic device.

FIGS. 3-11 are partial side elevation views of the electronic device of FIG. 1 undergoing fabrication processing according to an implementation of the method of FIG. 2.

FIGS. 12-20 are partial side elevation views of the electronic device of FIG. 1 undergoing fabrication processing according to an implementation of the method of FIG. 2.

FIG. 21 is a sectional side elevation view of an electronic device with stacked first and second dies with aligned respective first and second coils.

FIG. 22 is a sectional side elevation view of another electronic device with stacked first and second dies with aligned respective first and second coils.

FIG. 23 is a sectional side elevation view of a further electronic device with stacked first and second dies with aligned respective first and second coils.

FIG. 24 is a sectional side elevation view of another electronic device with stacked first and second dies with aligned respective first and second coils.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/−10 percent of the stated value. One or more structures, features, aspects, components, etc., may be referred to herein as first, second, third, etc., such as first and second terminals, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

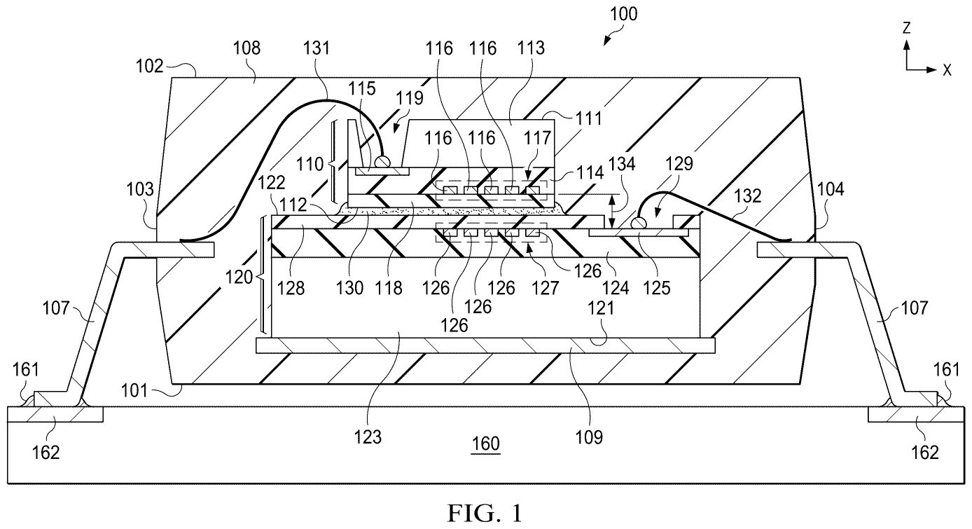

FIG. 1 shows a compact electronic device 100 with stacked semiconductor dies including a first semiconductor die 110 and a second semiconductor die 120. The first semiconductor die 110 in this example is attached to (e.g., stacked on) the second semiconductor die 120. The first semiconductor die 110 in this example arrangement can be referred to as a stacked or top die and the second semiconductor die 120 can be referred to as a base or bottom die. The electronic device 100 also has on-board, integrated magnetic features, such as transformer coils that provide isolated inductive power and/or signal transfer between the first and second semiconductor dies 110 and 120. The electronic device also includes conductive metal leads 107. The electronic device 100 is shown in an example three-dimensional space with a first direction X, a perpendicular (orthogonal) second direction (into the page in FIG. 1), and a third direction Z that is perpendicular (orthogonal) to the respective first and second directions. Structures or features along any two of these directions are orthogonal to one another.

The electronic device 100 has a molded package structure 108 with opposite first and second sides 101 and 102 (e.g., bottom and top), respectively, which are spaced apart from one another along the third direction Z in the illustrated position. The package structure 108 encloses interior portions of the leads 107 and outer portions of the leads 107 extend outside the respective third and fourth sides 103 and 104 of the package structure 108. The electronic device 100 also has laterally opposite third and fourth sides 103 and 104 that are spaced apart from one another along the first direction X, and fifth and sixth sides (not shown in FIG. 1) that are spaced apart from one another along the second direction. The package structure 108 at least partially encloses the semiconductor dies 110 and 120. The electronic device 100 also includes a die attach pad 109 that supports the second semiconductor die 120.

The vertically stacked arrangement of the semiconductor dies 110 and 120 facilitates a compact form factor device with integrated transformer coupling between separate isolated voltage domains. The dies 110 and 120 are stacked in a face to face configuration in this example, with the die front sides facing one another. The first semiconductor die 110 has a first side 111 (e.g., the die back side) and an opposite second side 112 (e.g., the die front side), and the sides 111, 112 are spaced apart from one another along the third direction Z. The first semiconductor die 110 includes a semiconductor layer 113, such as silicon, and a first metallization structure 114 on the semiconductor layer 113.

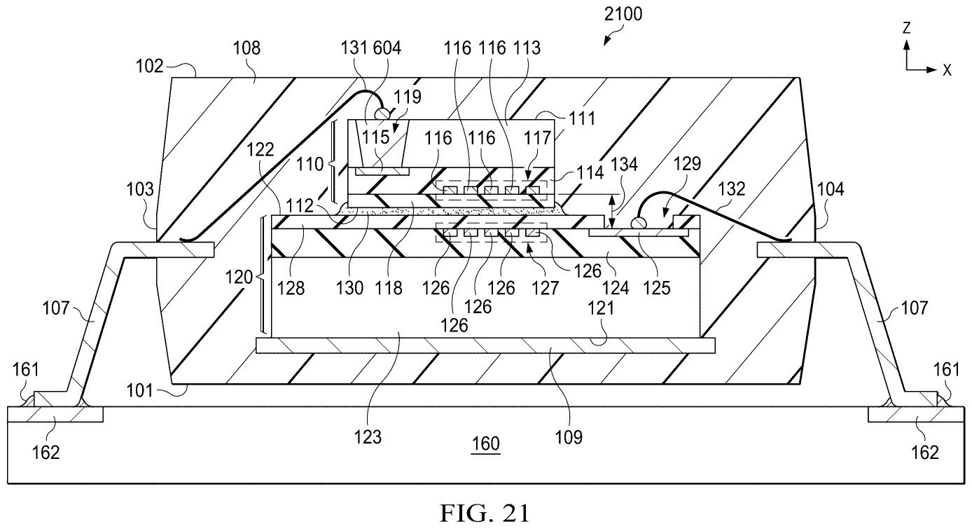

The first metallization structure 114 has multiple levels or layers that individually include conductive metal features (e.g., copper, aluminum, etc.) and inter level dielectric (ILD) material such as silicon dioxide (SiO₂, etc.). The first terminal 115 includes a metal feature in the first or lowest layer of the first metallization structure 114 that is closest to the semiconductor layer 113 and farthest from the second semiconductor die 120. The first terminal 115 in one example is a first bond pad 115 that is or includes a conductive metal such as aluminum or copper exposed along the first side 111 of the first semiconductor die 110. In other examples, the first terminal could be, or be coupled to, a conductive metal via, such as a through-silicon via (TSV), as shown in FIG. 21 below.

The first metallization structure 114 in FIG. 1 also has one or more conductive metal features 116 (e.g., turns) that form a first coil 117. The first coil 117 in the example of FIG. 1 includes metal features 116 of a final or uppermost layer of the first metallization structure 114 that is farthest from the semiconductor layer 113 and is closest to the second semiconductor die 120. In the illustrated example, the first semiconductor die 110 has a first dielectric layer 118, such as silicon dioxide (SiO₂, etc.). The first dielectric layer 118 extends on the first metallization structure 114 on the second side 112 of the first semiconductor die 110. A back side trench 119 extends into the first side 111 of the first semiconductor die 110 to expose a side of the first terminal 115. The first terminal 115 is contacted by a first bond wire 131 through the trench 119 and the bond wire 131 is enclosed by the package structure 108.

The second semiconductor die 120 has a back or first side 121 attached to the die attach pad 109, as well as an opposite front or second side 122 facing the second side 112 of the first semiconductor die 110. The second semiconductor die 120 includes a semiconductor layer 123, such as silicon along the first side 121, and a second metallization structure 124 on the semiconductor layer 123. The second metallization structure 124 includes a second terminal 125 and conductive metal features 126 (e.g., turns) that form a second coil 127 of the second semiconductor die 120. The second semiconductor die 120 also includes a second dielectric layer 128 (e.g., SiO₂, etc.) on the second side 122 of the second semiconductor die 120. The second dielectric layer 128 has an opening 129 that exposes a portion of the top side of the second contact 125. The second terminal 125 in one example is a second bond pad 125 that is or includes a conductive metal such as aluminum or copper exposed along the second side 121 of the second semiconductor die 120. The second terminal 125 is contacted by a second bond wire 132 through the opening 129 and the package structure 108 fills the opening 129 and encloses the second bond wire 132. The example electronic device 100 can also include additional surface mount components (not shown), for example, one or more capacitors, resistors, diode, etc. that can be enclosed by the package structure 108 and electrically coupled to the circuitry of one or more of the semiconductor dies 110 and 120.

The electronic device 100 in FIG. 1 has a face to face stacked die configuration with the front or second side 112 of the first semiconductor die 110 facing the front or second side 122 of the second semiconductor die 120. The first dielectric layer 118 of the first semiconductor die 110 is attached to the dielectric layer 128 of the second semiconductor die 120 by a non-conductive die attach film or adhesive 130 such that the second side 112 of the first semiconductor die 110 is attached to and faces the second side 122 of the second semiconductor die 120. The thicknesses of the dielectric layers 118 and 128 and of the non-conductive adhesive 130 is set for a desired spacing distance 134 between the coils 117 and 127 along the third direction Z to accommodate a designed electrical isolation rating for the electronic device 100.

The first bond wire 131 has a first end coupled to the first terminal 115 and a second end coupled to a first one of the conductive metal leads 107 inside the package structure 108. The second bond wire 132 has a first end coupled to the second terminal 125 and a second end coupled to a second one of the conductive metal leads 107 inside the package structure 108. FIG. 1 shows a partial system view of a system with a circuit board 160 having first and second conductive features 162. The system includes the electronic device 100 with the first terminal 115 electrically coupled to the first conductive feature 162 of the circuit board 160 by the bond wire 131 and solder 161 that connects the first lead 107 to the first conductive feature 162. The second terminal 125 is electrically coupled to the second conductive feature 162 of the circuit board 160 by a corresponding solder connection 161 and the second lead 107.

The semiconductor dies 110 and 120 are aligned laterally along the first direction X and the orthogonal second direction (into the page in the view of FIG. 1) such that the second coil 127 is aligned to the first coil 117. The lateral alignment of the coils 117 and 127 facilitates operative magnetic coupling for signal and/or power transfer between the coils 117 and 127 while the coils 117 and 127 remain electrically isolated from one another. As used herein, the first and second coils 117 and 127 are aligned when the location of corresponding conductive features 116 and 126 are within 10% of design locations as a percentage of the smaller of the line or conductive feature widths of the conductive features 116 and 126. Lateral alignment of the coils 117 and 127 in certain examples is affected by wafer processing variations in creating the conductive features 116, 126 during fabrication of the first and second semiconductor dies 110 and 120, as well as during attachment of the first semiconductor die 110 to the second semiconductor die 120. Perfect alignment is not required, and the first and second coils 117 and 127 are aligned such that operative magnetic coupling of the coils 117 and 127 allows power and/or signal transfer between the coils 117 and 127.

In one example, the first and second coils 117 and 127 are designed to be of the same feature widths (e.g., line widths of the conductive features 116 and 126 along the first direction X in FIG. 1) and the coils 117 and 127 are aligned such that centers of the coextensive portions of the lines or features 116 and 126 are within 10% of the design line or conductive feature widths in the first and second directions from the relative design center position in the first and second directions. The coils 117 and 127 are also aligned when the coils structures in the respective metallization structures 114 and 124 are within 10 degrees of coplanarity. The coils 117 and 127 can be of any suitable shapes or patterns that provide magnetic coupling to allow power and/or signa transfer, for example, spiral, etc. The coils 117 and 127 and the conductive features 116 and 126 thereof need not be designed to be coextensive or the same and can be of different sizes and shapes or patterns. The coils 117 and 127 can have the same or different numbers of turns. The individual coils 117 and 127 can have turns or portions 116, 126 in a single layer or level of a respective metallization structure 114, 124 or can have turns or portions 116, 126 in more than one layer or level of the respective metallization structure 114, 124. Either or both of the semiconductor dies 110 or 120 can have more than one coil to form a transformer with two or more windings (e.g., primary and secondary) or a single primary in one die 110, 120 with two or more secondary windings in the other die 120, 110, and/or multiple transformers can be provided with transformer coupling between respective coils of the first and second dies 110, 120.

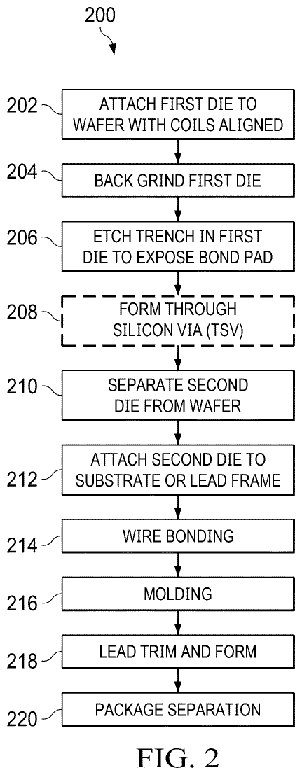

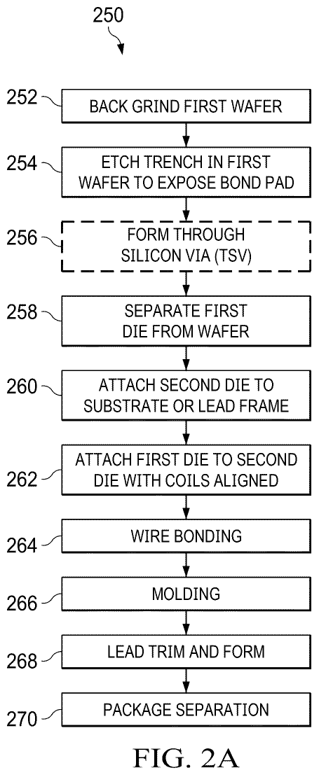

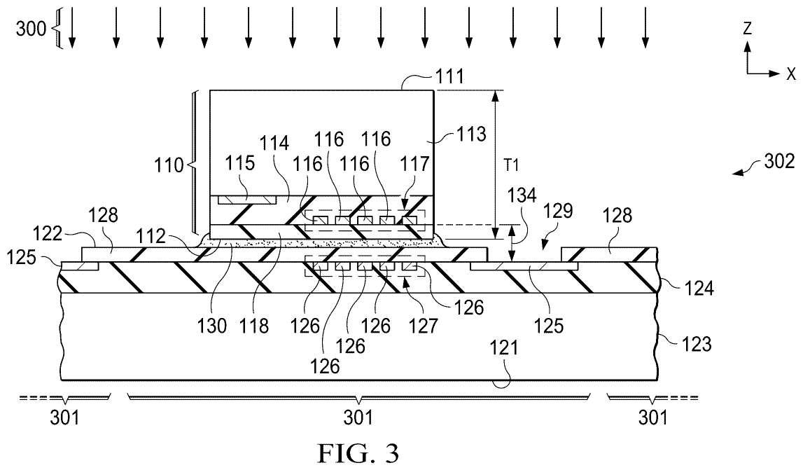

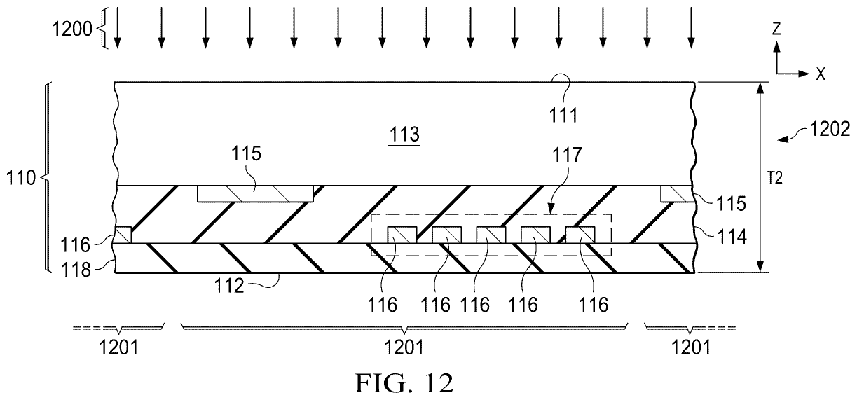

Referring now to FIGS. 2-11, FIG. 2 shows a first example method 200 of fabricating an electronic device using chip to wafer attachment and FIGS. 3-11 show partial side elevation views of the example electronic device 100 of FIG. 1 undergoing fabrication processing according to an implementation of the method 200 of FIG. 2. FIG. 2A shows another example method 250 of fabricating an electronic device using die to die attachment and FIGS. 12-20 show the example electronic device 100 of FIG. 1 undergoing fabrication processing according to an implementation of the method 250 as described further below.

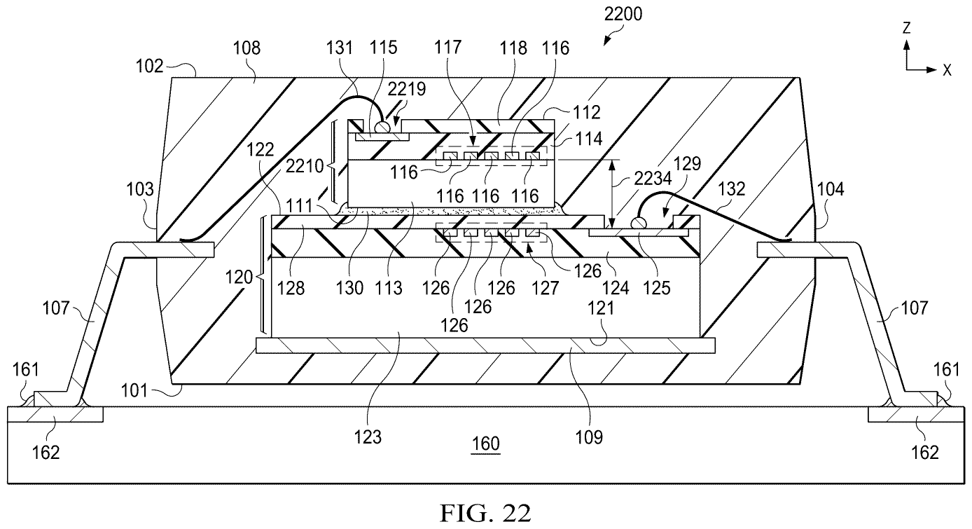

The methods 200 and 250 can be implemented to create face to face stacked die arrangements as exemplified by the semiconductor device 100 in FIG. 1 and the examples of FIGS. 21, 23 and 24 described further below. Other implementations of the methods 200 or 250 can be used to create different stacked arrangements, such as a face up stack (e.g., FIG. 22 below). Various implementations can include a variety of different electrical coupling technologies, including flip chip die attachment, wire bonding, etc., and can be used in packages that include conductive metal features created using a lead frame and/or substrate-based packaging, and can accommodate incorporation of other components (e.g., surface mount capacitors, resistors, diodes, etc.) within a packaged electronic device.

The method 200 in FIG. 2 begins with chip to wafer attachment at 202 to attach an instance of the first semiconductor die 110 to the second side 122 of a second semiconductor die unit area of a wafer. FIG. 3 shows one example, in which a die attach process 300 is performed with respect an illustrated unit area 301 of a wafer 302 that has multiple unit areas 301. In one example, the wafer 302 is being processed to create instances of the above described second semiconductor die 120 in each unit area 301, such as unit areas 301 in rows and columns along a front or top side 122 of the wafer 302 that corresponds to the second side 122 of each fabricated second semiconductor die 120. In the illustrated example, moreover, the first semiconductor die 110 is illustrated after previous wafer processing and die singulation (not shown), with the total die thickness T1 having an initial value, in consideration of subsequent back grinding of the back or first side 111 of the semiconductor die 110.

The die attach process 300 in FIG. 3 attaches the first semiconductor die 110 to the second side 122 of the prospective second semiconductor die 120 of the wafer with the first coil 117 of the first semiconductor die 110 aligned with the second coil 127 of the prospective second semiconductor die 120, for example, using automated pick and place equipment (not shown). The alignment in one example is implemented by control of the pick and place equipment with respect to the position of the first semiconductor die 110 relative to the position of the associated unit area of the processed wafer such that the first coil 117 of the first semiconductor die 110 is aligned with the second coil 127 of the corresponding wafer unit area, for example, using optical alignment equipment (not shown). In the illustrated example, the first dielectric layer 118 of the first semiconductor die 110 is attached by the die attach film or adhesive 130 to the top side 122 of the second dielectric layer 128 of the wafer 302. The attachment process 300 sets the spacing distance 134 between the coils 117 and 127 along the third direction Z according to a designed electrical isolation rating for the electronic device 100. The process 300 in one example includes initially forming (e.g., depositing, dispensing, silk screening, etc.) the die attach film or adhesive 130 to an initial thickness along the third direction Z such that the subsequent attachment force that engages the first semiconductor die 110 to the die attach film or adhesive 130 and any subsequent adhesive curing processing provides the desired spacing 134 between the first and second coils 117 and 127 along the third direction Z.

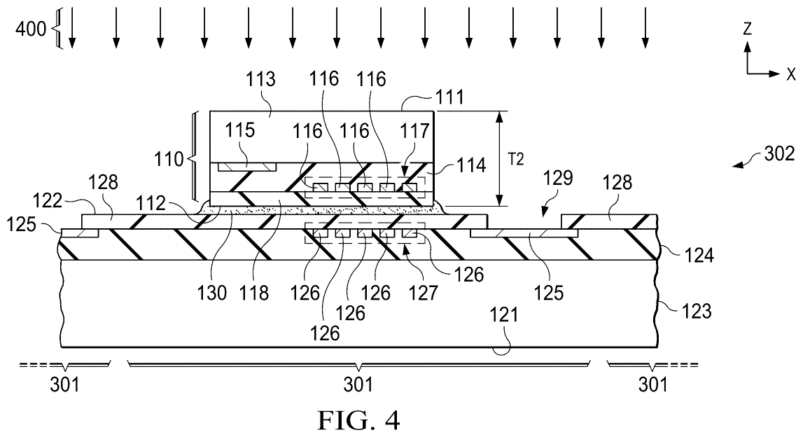

The method 200 in one example continues at 204 in FIG. 2 with back grinding of the first semiconductor die 110. The back grinding in one example can be a concurrent process that grinds the back or first sides 111 of each instance of the first semiconductor die 110 attached in the respective unit areas 301 of the wafer 302. FIG. 4 shows one example, in which a back grinding process 400 is performed that selectively removes material from the first side 111 of the attached first semiconductor die 110, and the process 400 is continued until a final desired thickness T2 of the first semiconductor die 110 is achieved. The final thickness T2 of the first semiconductor die 110 can be adjusted according to final package size specifications of a given electronic device design (e.g., approximately 20 μm). In another implementation, the back grinding at 204 in FIG. 2 can be omitted, for example, where back grinding of the first semiconductor die 110 is performed during wafer processing before the first semiconductor die 110 is separated or cingulate in from a first wafer (not shown).

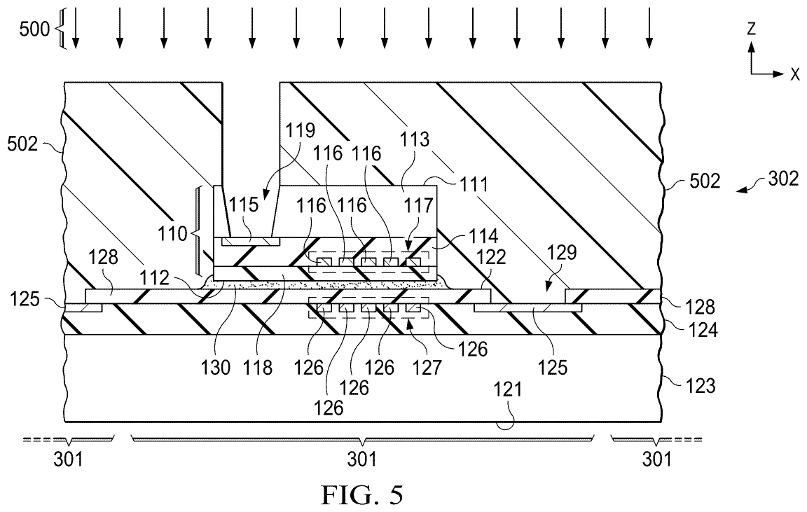

The method 200 continues at 206 and FIG. 2 with etching to form a trench in the back or first side 111 of the first semiconductor die 110 in order to expose the first terminal 115 (e.g., bond pad). FIG. 5 shows one example, in which an etch process 500 is performed with a patterned etch mask 502 that exposes a portion of the first side 111 of the first semiconductor die 110 in each unit area 301. Any suitable mask formation and patterning processing steps and materials can be used to form the patterned mask 502 (e.g., spray coating a layer of resist, exposing the deposited resist layer, and developing the exposed photo resist. In addition, any suitable etch chemistry can be used for the process 500 (e.g., plasma etching), which selectively removes semiconductor material (e.g., silicon) to form the trench 119 that exposes a side of the first conductive terminal 115, followed by resist removal (e.g., stripping). In the illustrated example, the first terminal 115 is in an initial layer of a multilayer metallization structure 114 of the first semiconductor die 110, which is nearest to the semiconductor layer 113 and farthest from the first dielectric layer 118. The etch process 500 can include further cleaning steps (not shown) in order to prepare the exposed surface of the first terminal 115 for subsequent electrical connection processing (e.g., wire bonding).

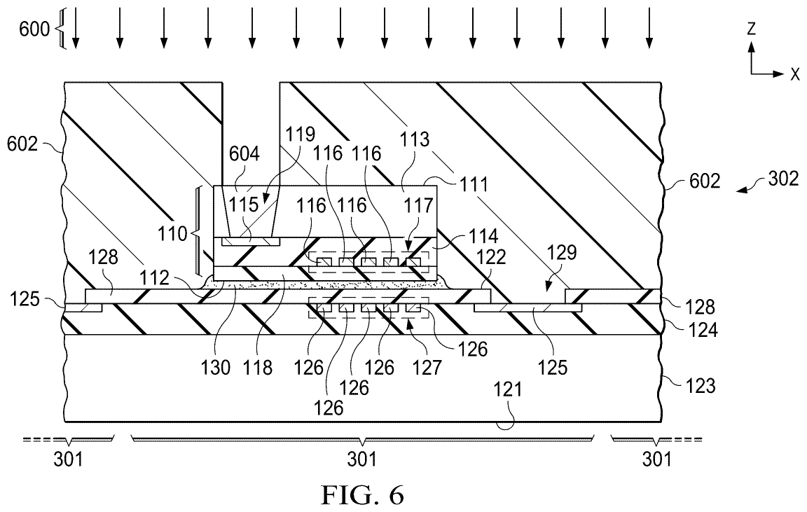

In one implementation, the method 200 can include through silicon via (TSV) formation at 208 in FIG. 2. FIG. 6 shows one example, in which a deposition process 600 is performed that deposits conductive metal sees e.g., copper, aluminum, etc.) in the previously formed trench 119 to form a conductive metal via 604 in the trench 119. In one example, the deposition process 600 is performed using a deposition mask 602. In other implementations, the mask 602 can be omitted. In one example, the deposition process 600 can be a copper electroplating process that selectively deposits copper 604 on the first terminal 115 and continues deposition until the top side of the deposited copper via 604 is approximately planar with the first side 111 of the first semiconductor die 110. In other implementations, the through silicon via processing at 208 in FIG. 2 can be omitted.

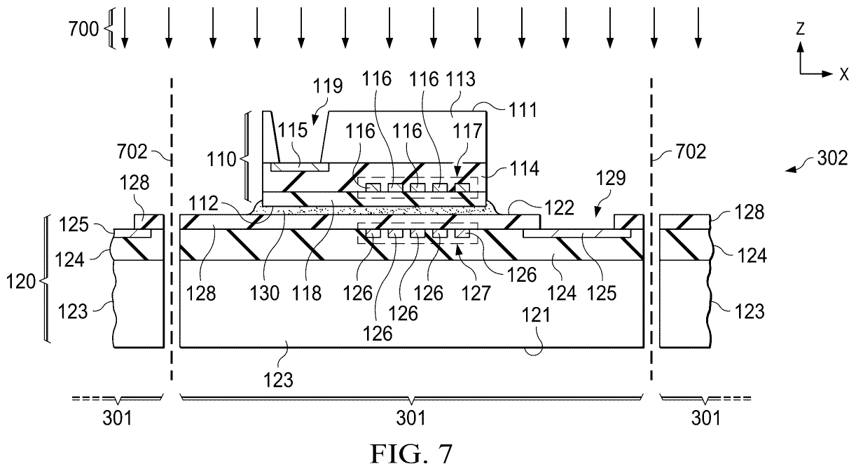

The method 200 continues at 210 with separating the second semiconductor die 120 from the wafer 302. FIG. 7 shows one example (with a portion of the first contact 115 exposed in the trench 119, without the optional through silicon via), in which a die singulation process 700 is performed that separates instances of the second semiconductor die 120 from the wafer 302 along separation lines 702. Any suitable package separation process 700 can be used, for example, saw cutting, laser cutting, chemical etching, etc., or combinations thereof. The separated second semiconductor die 120 has an instance of the first semiconductor die 110 attached to provide a stacked die component that can be further processed for packaging as described below.

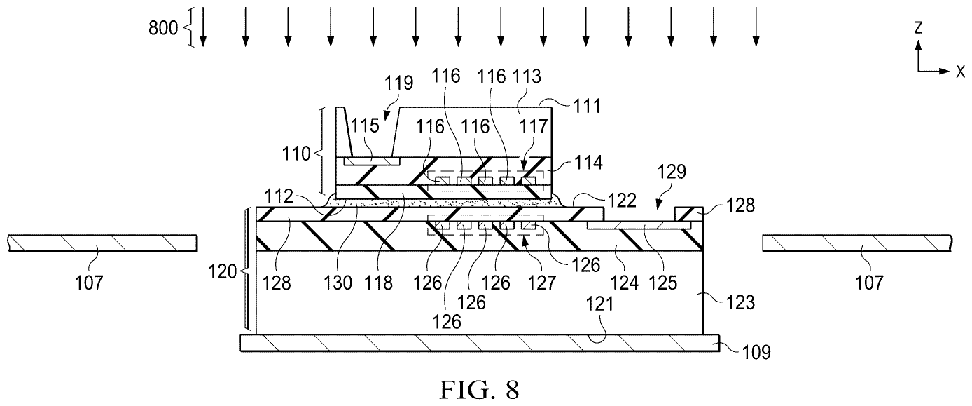

At 212 in FIG. 2, the method 200 further includes a second die attachment to attach the second semiconductor die 120 to a substrate or lead frame. FIG. 8 shows one example, using a starting lead frame. The lead frame in one example is a panel array structure with rows and columns of unit areas, each having a die attach pad 109 and prospective leads 107. FIG. 8 shows one example unit area of the starting lead frame, in which a die attach process 800 is performed that attaches the back or first side 121 of the second semiconductor die 120 to a top side of the die attach pad 109. Any suitable die attachment processing 800 can be used, for example, forming a die attach film or adhesive (not shown) on a portion of the top side of the die attach pad 109 in each unit area, followed by attachment of the second semiconductor die 120 to the die attach film on the die attach pad 109, for example, using automated pick and place equipment (not shown).

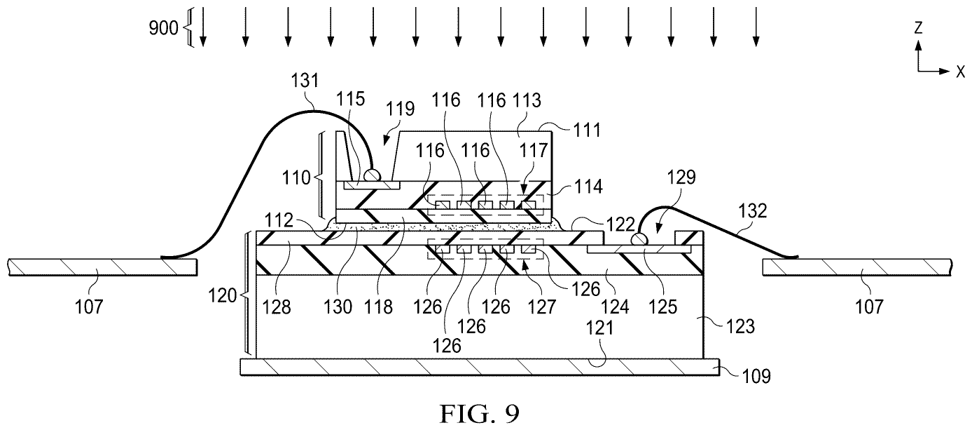

The method 200 continues at 214 in FIG. 2 with electrical connection, in one example including wire bonding. FIG. 9 shows one example, in which a wirebonding process 900 is performed that forms the first bond wire 131 between the first terminal 115 of the first semiconductor die 110 and a first prospective lead 107 in the illustrated unit area of the lead frame panel array. The first bond wire 131 connects to the exposed top side of the first terminal 115 through the trench 119 etched in the semiconductor layer 113 of the first semiconductor die 110. The wirebonding process 900 also forms a second bond wire 132 connecting the second terminal 125 of the second semiconductor die 120 to a second prospective lead 107 in the illustrated unit area. The second bond wire 132 is connected to the exposed top side of the second terminal 125 through the opening 129 in the second dielectric layer 123 of the second semiconductor die 120. In other implementations, other types and forms of electrical connection processing can be performed, for example, using conductive metal clips, flip-chip electrical interconnections (not shown) alone or in combination with wire bonding.

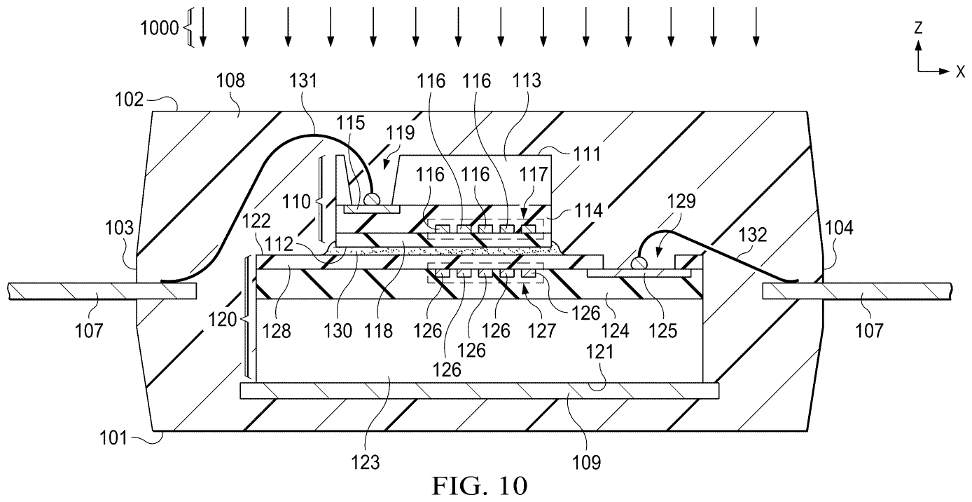

The method 200 continues at 216 in FIG. 2 with molding processing to form the molded package structure 108. FIG. 10 shows one example, in which a molding process 1000 is performed to form the molded package structure 108 that encloses the bond wires 131, 132, the semiconductor dies 110, 120, the die attach pad 109 and interior portions of the prospective leads 107 in each unit area of the lead frame panel array. In one example, a single mold cavity can be used to form a unitary magnetic molded structure 108 that extends across all the rows and columns of the lead frame panel array structure. In another implementation, individual mold cavities can be used to form respective molded magnetic package structures 108 in each unit area. In other implementations, the individual mold cavities can extend across two or more unit areas of the lead frame panel array structure, for example, to form package structures 108 along rows or columns of the array structure.

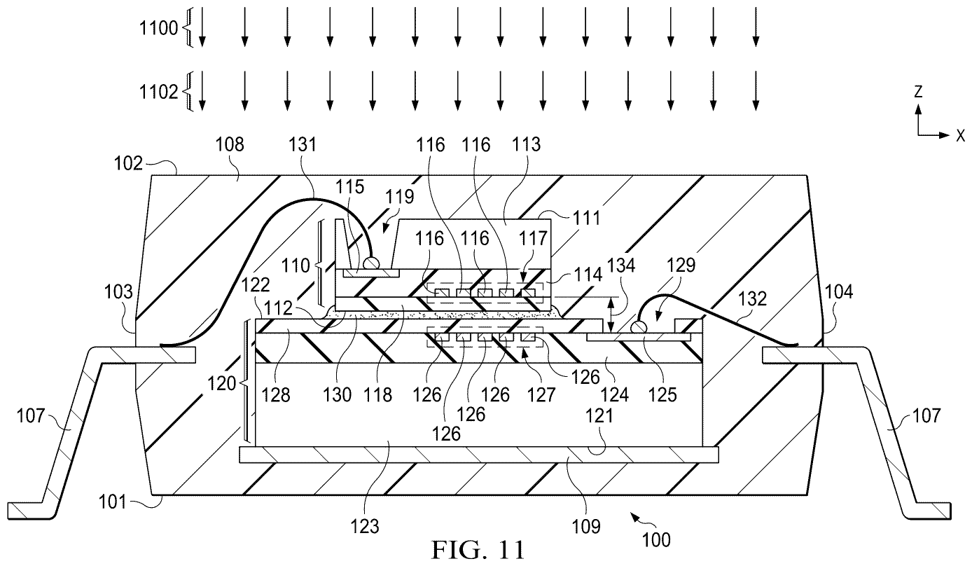

At 218 in FIG. 2, the method 200 includes trimming and forming operations. FIG. 11 shows one example, in which trimming and forming processes 1100 are performed that separate prospective leads 107 between adjacent unit areas of the starting lead frame panel array structure using cutting blades or other suitable equipment (not shown) and form the leads into the final desired shape (e.g., gullwing leads) using punch dies or other suitable tooling (not shown). The method 200 in one example can include optional plating (not shown) of the leads in each unit area of the panel array after molding at 216, which can be before, after or between lead trimming and forming at 218 in FIG. 2.

The method 200 in one example includes further package separation processing at 220 in FIG. 2. FIG. 11 further illustrates one example, in which an optional package separation process 1102 is performed that separates adjacent packaged electronic devices from one another along columns of the starting lead frame panel array structure to provide separated packaged electronic devices 100 as described above in connection with FIG. 1. In one example, the package separation process 1102 includes saw cutting to separate column length molded package structures formed at 216 in FIG. 2 from one another, and to cut through tie bars (not shown) that initially connect die attach pads 109 of adjacent unit areas along an array column.

Referring now to FIGS. 2A and 12-20, FIG. 2A shows another example method 250 of fabricating an electronic device and FIGS. 12-20 show the example electronic device 100 of FIG. 1 undergoing fabrication processing according to an implementation of the method 250.

The method 250 in FIG. 2A begins at 252 with back grinding a first wafer. FIG. 12 shows one example of a back grinding process 1200 performed with a first wafer 1202 with opposite first and second sides 111 and 112. The wafer 1202 includes one or more unit areas 1201 that individually correspond to a subsequently separated instance of the first semiconductor die 110. The wafer level back grinding in this example can mitigate or avoid difficulties associated with grinding a stacked arrangement as was the case in the method 200 of FIG. 2 described above. The back grinding process 1200 removes material from the first side 111 of a wafer 1202, and the process 1200 is continued until a final desired thickness T2 of the first semiconductor die 110 is achieved. The final thickness T2 of the first semiconductor die 110 can be adjusted according to final package size specifications of a given electronic device design (e.g., approximately 20 μm).

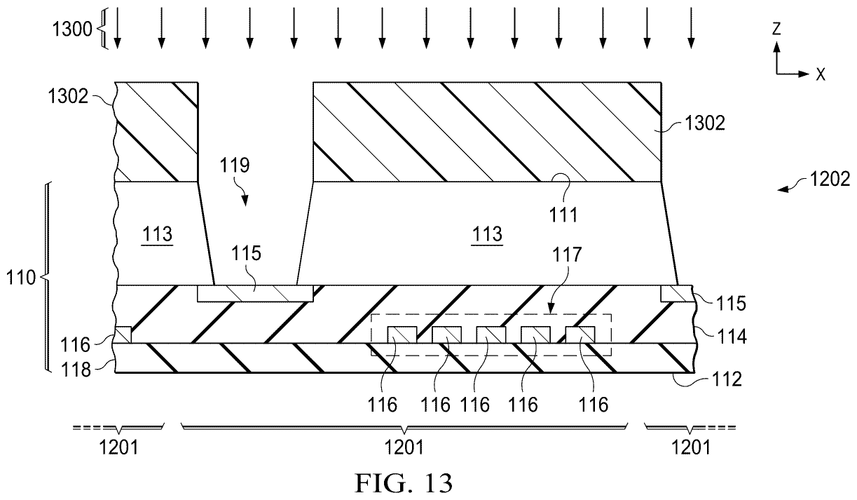

The method 250 continues at 254 and FIG. 2A with etching to form a trench in the back or first side 111 of the wafer 1202 in each respective unit area 1201 that corresponds to an individual first semiconductor die 110. The etching at 254 exposes the first terminal 115 (e.g., bond pad) of the metallization structure 114 of the wafer 1202 in each unit area 1201. FIG. 13 shows one example, in which an etch process 1300 is performed with a patterned etch mask 1302 that exposes a portion of the first side 111 of the wafer 1202 in each unit area 1201. Any suitable mask formation and patterning processing steps and materials can be used to form the patterned mask 1302 (e.g., spray coating a layer of resist, exposing the deposited resist layer, and developing the exposed photo resist. In addition, any suitable etch chemistry can be used for the process 1300 (e.g., plasma etching), which selectively removes semiconductor material (e.g., silicon) to form the trench 119 that exposes a side of the first conductive terminal 115, followed by resist removal (e.g., stripping). In the illustrated example, the first terminal 115 is in an initial layer of a multilayer metallization structure 114 of the first semiconductor die 110, which is nearest to the semiconductor layer 113 and farthest from the first dielectric layer 118. The etch process 1300 can include further cleaning steps (not shown) in order to prepare the exposed surface of the first terminal 115 for subsequent electrical connection processing (e.g., wire bonding).

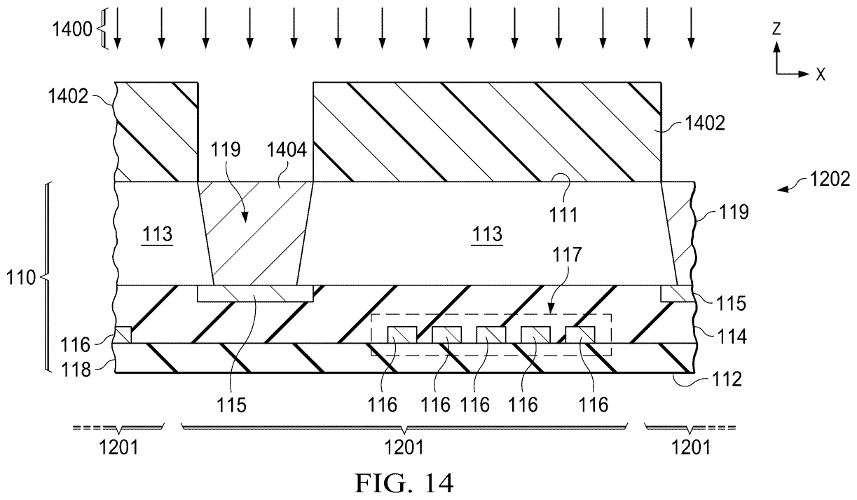

In one implementation, the method 250 can include through silicon via (TSV) formation at 256 in FIG. 2A. FIG. 14 shows one example, in which a deposition process 1400 is performed that deposits conductive metal sees e.g., copper, aluminum, etc.) in the previously formed trench 119 to form a conductive metal via 1404 in the trench 119. In one example, the deposition process 600 is performed using a deposition mask 1402. In other implementations, the mask 1402 can be omitted. In one example, the deposition process 1400 can be a copper electroplating process that selectively deposits copper 1404 on the first terminal 115 and continues deposition until the top side of the deposited copper via 1404 is approximately planar with the first side 111 of the first semiconductor die 110. In other implementations, the through silicon via processing at 256 in FIG. 2A can be omitted.

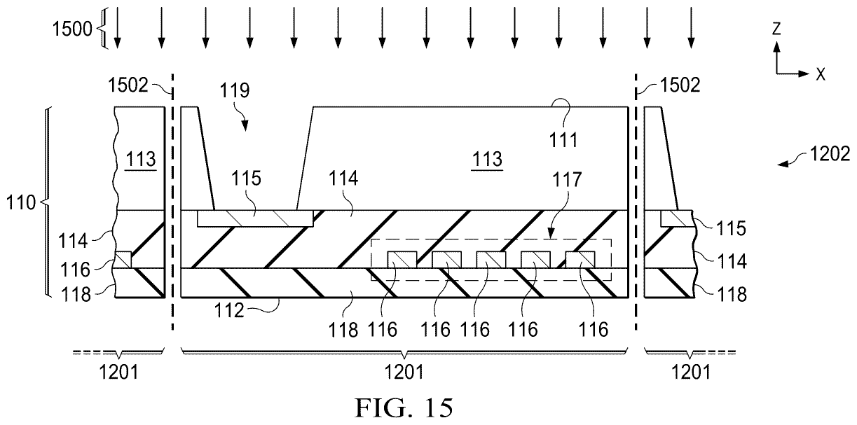

The method 250 continues at 258 in FIG. 2A with separating the first semiconductor die 110 from the wafer 1202. FIG. 15 shows one example (with a portion of the first contact 115 exposed in the trench 119, without the optional through silicon via), in which a die singulation process 1500 is performed that separates instances of the first semiconductor die 110 from the wafer 1202 along separation lines 1502. Any suitable package separation process 1500 can be used, for example, saw cutting, laser cutting, chemical etching, etc., or combinations thereof.

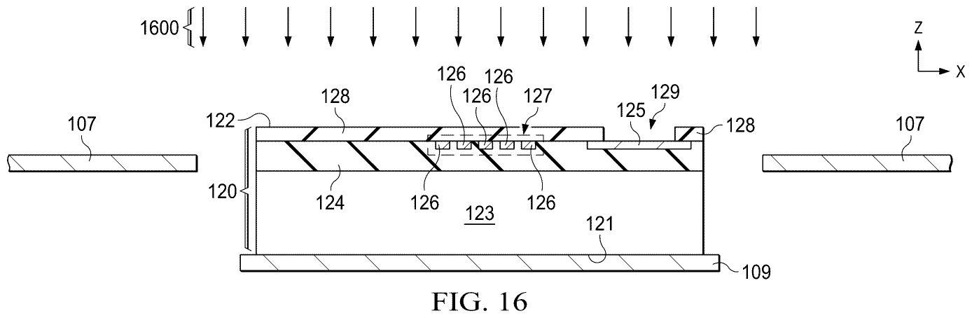

At 260 in FIG. 2A, the method 250 continues with first die attach processing to attach the second semiconductor die 120 to a substrate or lead frame. In this example, instances of the second semiconductor die 120 have been previously processed at the wafer level and separated from a wafer. FIG. 16 shows one example of the attachment at 260 using a starting lead frame. The lead frame in one example is a panel array structure with rows and columns of unit areas, each having a die attach pad 109 and prospective leads 107. FIG. 16 shows one example unit area of the starting lead frame, in which a die attach process 1600 is performed that attaches the back or first side 121 of the second semiconductor die 120 to a top side of the die attach pad 109. Any suitable die attachment processing 1600 can be used, for example, forming a die attach film or adhesive (not shown) on a portion of the top side of the die attach pad 109 in each unit area, followed by attachment of the second semiconductor die 120 to the die attach film on the die attach pad 109, for example, using automated pick and place equipment (not shown).

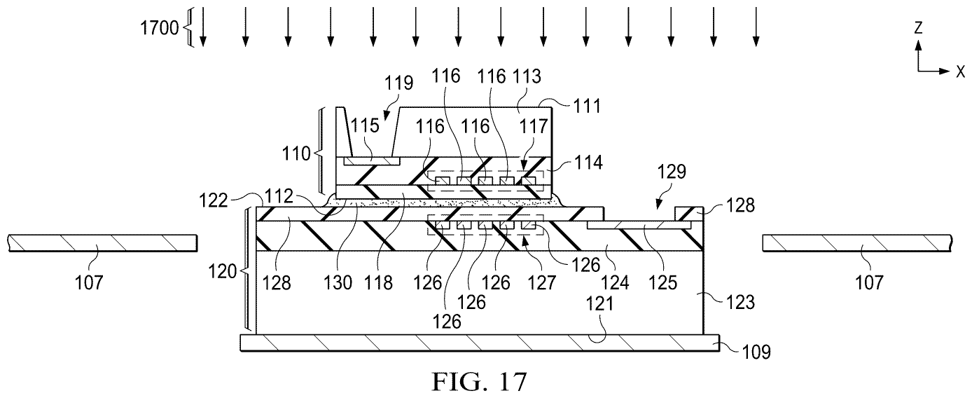

The method 250 continues at 262 in FIG. 2A with chip to chip die attachment to attach the separated first semiconductor die 110 to the second side 122 of the second semiconductor die 120 after the second semiconductor die 120 has been attached to the lead frame or substrate. FIG. 17 shows one example, in which a die attach process 1700 is performed that attaches the first semiconductor die 110 to the second side 122 of the second semiconductor die 120 with the first coil 117 of the first semiconductor die 110 aligned with the second coil 127 of the second semiconductor die 120, for example, using automated pick and place equipment (not shown). The alignment in one example is implemented by control of the pick and place equipment with respect to the position of the first semiconductor die 110 relative to the position of the associated unit area of the processed wafer such that the first coil 117 of the first semiconductor die 110 is aligned with the second coil 127 of the corresponding wafer unit area, for example, using optical alignment equipment (not shown). In the illustrated example, the first dielectric layer 118 of the first semiconductor die 110 is attached by the die attach film or adhesive 130 to the top side 122 of the second dielectric layer 128 of the wafer 1702. The attachment process 1700 sets the spacing distance 134 between the coils 117 and 127 along the third direction Z according to a designed electrical isolation rating for the electronic device 100. The process 1700 in one example includes initially forming (e.g., depositing, dispensing, silk screening, etc.) the die attach film or adhesive 130 to an initial thickness along the third direction Z such that the subsequent attachment force that engages the first semiconductor die 110 to the die attach film or adhesive 130 and any subsequent adhesive curing processing provides the desired spacing 134 between the first and second coils 117 and 127 along the third direction Z.

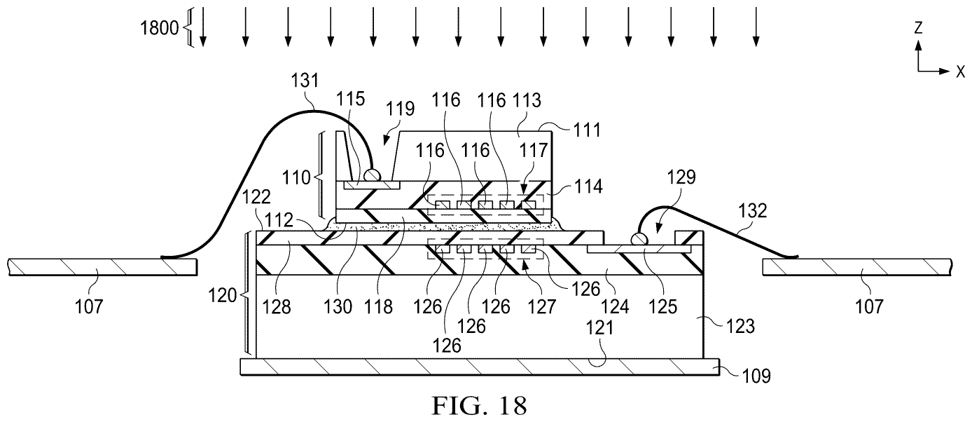

The method 250 continues at 264 in FIG. 2A with electrical connection, in one example by wire bonding. FIG. 18 shows one example, in which a wirebonding process 1800 is performed that forms the first bond wire 131 between the first terminal 115 of the first semiconductor die 110 and a first prospective lead 107 in the illustrated unit area of the lead frame panel array. The first bond wire 131 connects to the exposed top side of the first terminal 115 through the trench 119 in the semiconductor layer 113 of the first semiconductor die 110. The wirebonding process 1800 also forms a second bond wire 132 between the second terminal 125 of the second semiconductor die 120 and a second prospective lead 107 in the illustrated unit area. The second bond wire 132 is connected to the exposed top side of the second terminal 125 through the opening 129 in the second dielectric layer 123 of the second semiconductor die 120. In other implementations, other types and forms of electrical connection processing can be performed, for example, using conductive metal clips, flip-chip electrical interconnections (not shown) alone or in combination with wire bonding.

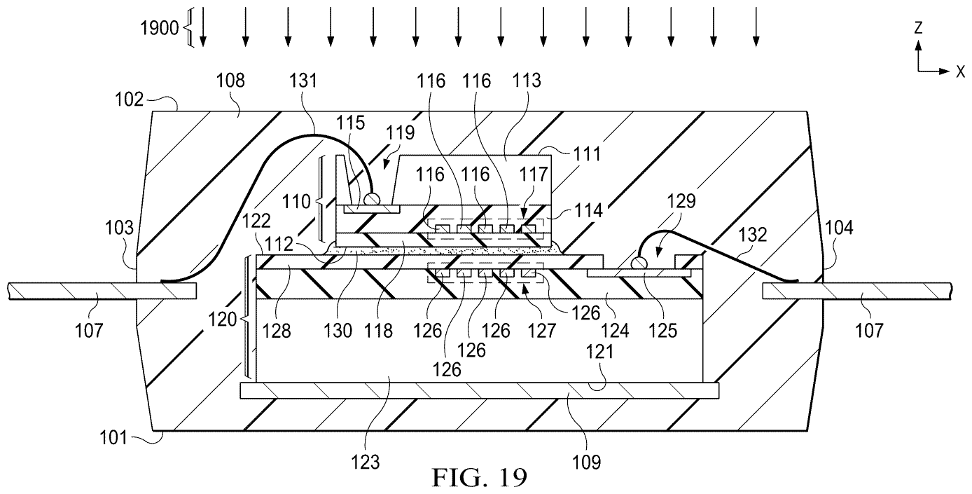

The method 250 continues at 266 in FIG. 2A with molding processing to form the molded package structure 108. FIG. 19 shows one example, in which a molding process 1900 is performed to form the molded package structure 108. The package structure in this example encloses the bond wires 131, 132, the semiconductor dies 110, 120, the die attach pad 109 and interior portions of the prospective leads 107 in each unit area of the lead frame panel array. In one example, a single mold cavity can be used to form a unitary magnetic molded structure 108 that extends across all the rows and columns of the lead frame panel array structure. In another implementation, individual mold cavities can be used to form respective molded magnetic package structures 108 in each unit area. In other implementations, the individual mold cavities can extend across two or more unit areas of the lead frame panel array structure, for example, to form package structures 108 along rows or columns of the array structure.

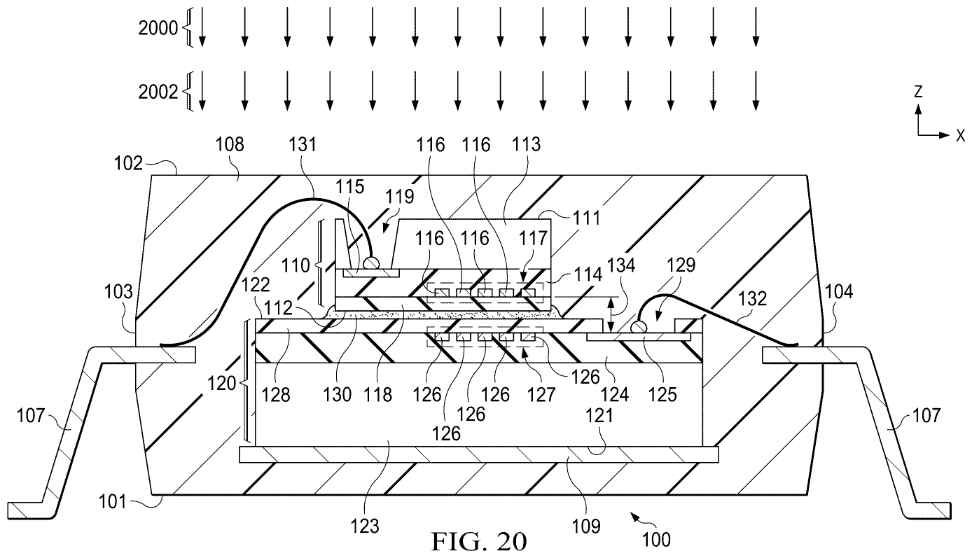

At 268 in FIG. 2A, the method 250 includes trimming and forming operations. FIG. 20 shows one example, in which trimming and forming processes 2000 are performed that separate prospective leads 107 between adjacent unit areas of the starting lead frame panel array structure using cutting blades or other suitable equipment (not shown) and form the leads into the final desired shape (e.g., gullwing leads) using punch dies or other suitable tooling (not shown). The method 250 in one example can include optional plating (not shown) of the leads in each unit area of the panel array after molding at 266, which can be before, after or between lead trimming and forming at 268 in FIG. 2A.

The method 250 in one example includes further package separation processing at 270 in FIG. 2A. FIG. 20 further illustrates one example, in which an optional package separation process 2002 is performed that separates adjacent packaged electronic devices from one another along columns of the starting lead frame panel array structure to provide separated packaged electronic devices 100 as described above in connection with FIG. 1. In one example, the package separation process 2002 includes saw cutting to separate column length molded package structures formed at 266 in FIG. 2A from one another, and to cut through tie bars (not shown) that initially connect die attach pads 109 of adjacent unit areas along an array column.

FIG. 21 shows a sectional side elevation view of an electronic device 2100 with stacked first and second semiconductor dies 110 and 120 (face to face) with aligned first and second coils 117 and 127, respectively. The electronic device 2100 includes similarly numbered structures, features, components, etc. as described above in connection with the electronic device 100 of FIG. 1. In this example, the first terminal of the first semiconductor die 110 includes a conductive metal via 604 (e.g., copper) that extends in the trench 119 on the top surface of the conductive metal terminal 115 of the first metallization structure 114 and is exposed along a first side 111 of the first semiconductor die 110. As described above in connection with FIGS. 6 and 14, the conductive metal via 604 can be formed during wafer processing of a first wafer from which the first semiconductor die 110 is separated (e.g., method 200 in FIGS. 2 and 6 above) or the trench 119 and the conductive metal via 604 can be formed during packaging following attachment of the first semiconductor die 110 to the second semiconductor die 120 (e.g., method 250 in FIGS. 2A and 14 above). In this example, the first bond wire 131 of the electronic device 2100 has a first end connected to a top side of the conductive metal via 604 and a second end connected to the first terminal 107.

FIG. 22 shows another example electronic device 2200 with respective stacked first and second semiconductor dies 2210 and 120 with aligned first and second coils 117 and 127, respectively. The electronic device 2200 in FIG. 22 has similarly numbered structures, features, components, etc. as described above in connection with the electronic device 100 of FIG. 1. In this example, the first side 111 of the first semiconductor die 2210 is attached to and faces the second side 122 of the second semiconductor die 120. The front or second side 112 of the first semiconductor die 2210 faces away from the second semiconductor die 120 (e.g., in a face up stack arrangement), and the back or first side 111 of the first semiconductor die 2210 is attached by the die attach adhesive 130 to the front or second side 122 of the second semiconductor die 120. In the electronic device 2200 of FIG. 22, the first coil 117 of the first semiconductor die 2200 includes metal features 116 of the lowest layer of the first metallization structure 114 that is closest to the second semiconductor die 120. The first terminal 115 includes a metal feature 115 in an uppermost layer of the first metallization structure 114 that is farthest from the second semiconductor die 120, and the first terminal 115 is contacted by the first bond wire 131 through an opening 2219 in the first dielectric layer 118 of the first semiconductor die 110.

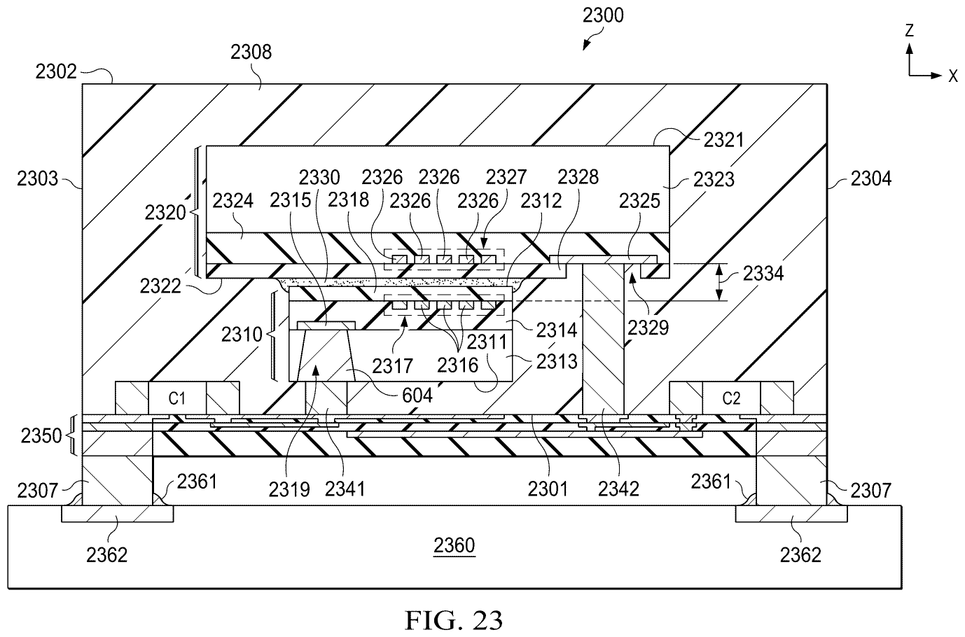

FIG. 23 shows a further example electronic device 2300 with respective stacked first and second dies 2310 and 2320 in a face to face arrangement with aligned first and second coils 2307 and 2327, respectively. The electronic device 2300 in FIG. 23 includes structures, features, components, etc. 2301-2304, 2307, 2308 and 2310-2330 that generally correspond to the structures, features, components, etc. 101-104, 107, 108, and 110-130 illustrated and described above in connection with the electronic device 100 of FIG. 1 unless described differently below. The electronic device 2300 is shown installed on a circuit board 2360 in a system configuration in FIG. 23 with conductive features 2362. The system includes the electronic device 2300 with the first terminal 2315 electrically coupled to the first conductive feature 2362 of the circuit board 2360 by the bond wire 2331 and solder 2361 that connects the first lead 2307 to the first conductive feature 2362. The second terminal 2325 is electrically coupled to the second conductive feature 2362 of the circuit board 2360 by a corresponding solder connection 2361 and the second lead 2307.

The electronic device 2300 has a multilevel package substrate 2350 (e.g., also referred to as a routable lead frame) with the leads 2307 configured to be soldered to the conductive features 2362 of the circuit board 2360. In this example, the terminals 2315 and 2325 of the respective first and second semiconductor dies 2310 and 2320 are flip chip soldered to corresponding conductive features on a top side of the multilevel package substrate 2350. The illustrated example also includes surface mount components (e.g., resistors, capacitors, inductors, further dies, etc.) such as capacitors C1 and C2 that are soldered to pads on the top side of the multilevel package substrate 2350 and couple the leads 2307 to the respective terminals 2315 and 1225 (e.g., for AC or capacitive differential signal coupling). In other implementations, the passive components C1 and C2 can be omitted, and/or the terminals 2315 and 2325 can be coupled directly to respective leads 2307 of the electronic device 2300.

The first semiconductor die 2310 has a back or first side 2311 connected to the front or second side 2322 of the second semiconductor die 2320 by die attach adhesive 2330. The front or second side 2312 of the first semiconductor die has a first semiconductor layer 2313 that is spaced apart from and faces the top side of the multilevel package substrate 2350. The first terminal 2315 of the first semiconductor die 2310 is a first metal pillar 2341 coupled to the die terminal 2315 and a conductive metal via 604 in the back side trench 2319 (e.g., as described above in connection with FIGS. 6, 14 and 21). The first metal pillar 2341 in one example is or includes a conductive metal (e.g., copper, aluminum, etc.) and is formed during fabrication, such as by a bumping process or electroplating (not shown). The pillar 2341 is flip chip attached (e.g., soldered) to a corresponding conductive metal feature (e.g., pad) on the top side of the multilevel package substrate 2350. The second terminal 2325 of the second semiconductor die 2320 has the die terminal 2315 coupled to a second metal pillar 2342 that is coupled (e.g., flip chip soldered) to a second conductive feature along the top side of the multilevel package substrate 2360. The conductive metal pads or features of the substrate 2352 which the metal pillars 2341 and 2342 are coupled can be routed to any suitable connection point, such as corresponding ones of the leads 2307 of the electronic device 2300, other components or dies (e.g., respective ones of the capacitors C1, C2), etc. In the illustrated example, the first terminal 2315 of the first semiconductor die 2310 is contacted by the metal via 604 in the trench 2319 that extends into the first side 2311 of the first semiconductor die 2310 to provide back side flip chip terminal connection to the substrate 2350 while positioning the first coil 2317 close to the second coil 2327.

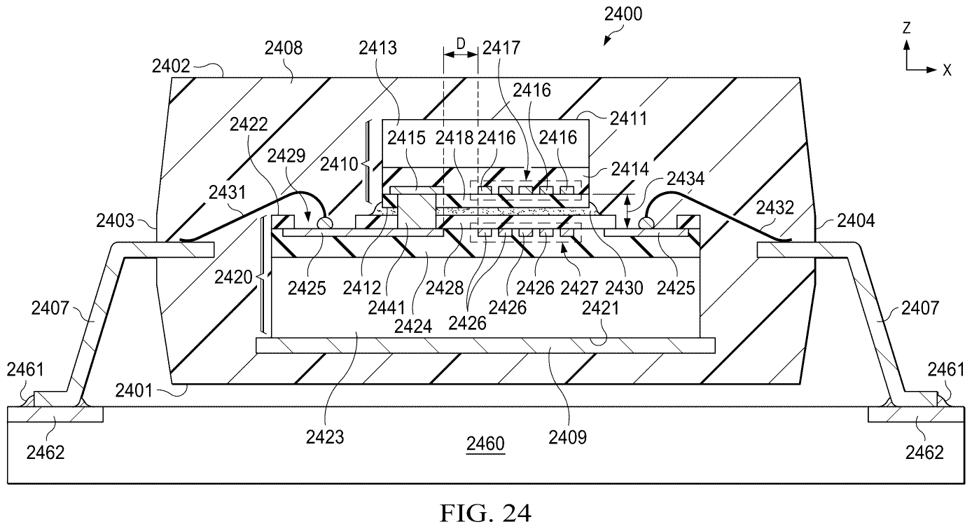

FIG. 24 shows another electronic device 2400 with respective stacked first and second dies 2410 and 2420 in another face to face arrangement with aligned respective first and second coils. The electronic device 2400 in FIG. 24 includes structures, features, components, etc. 2401-2404, and 2407-2432 that generally correspond to the structures, features, components, etc. 101-104, and 107-132 illustrated and described above in connection with the electronic device 100 of FIG. 1 unless described differently below. The electronic device 2400 is shown installed on a circuit board 2460 in a system configuration in FIG. 24 with conductive features 2462. The system includes the electronic device 2400 with the first terminal 2415 electrically coupled to the first conductive feature 2462 of the circuit board 2460 by the bond wire 2431 and solder 2461 that connects the first lead 2407 to the first conductive feature 2462. The second terminal 2425 is electrically coupled to the second conductive feature 2462 of the circuit board 2460 by a corresponding solder connection 2461 and the second lead 2407.

The electronic device 1400 of FIG. 24 has a face to face flip chip die to die attached structure with the first terminal 2415 of the first semiconductor die 2410 including a conductive metal pillar 2441 (e.g., copper, aluminum, etc.). In one example, the metal pillar 2441 is formed during fabrication of the first semiconductor die 2410, for example, by a bumping process (e.g., an electroplating). The conductive metal pillar 2441 is coupled to a first top metal feature 2425 of the second semiconductor die 2420, for example, by flip chip soldering. The first bond wire 2431 has a first end coupled (e.g., bonded) to the first top metal feature 2425 through a corresponding opening in the dielectric layer 2428 of the second semiconductor die 2420, and a second end coupled to a first one of the device leads 2407. The second terminal 2425 of the second semiconductor die 2420 is coupled by a second bond wire 2432 to another one of the device leads 2407. The flip chip attachment of the first semiconductor die 2410 to the second semiconductor die 2420 facilitates low-cost manufacturing while providing a face to face close positioning of the first and second coils 2417 and 2427, spaced apart by the spacing distance 2434. In addition, the example of FIG. 24 avoids backside etching of the first semiconductor die 2410 in order to provide a connection point for the first bond wire 2431. In addition, the electronic device 2400 of FIG. 24 does not require any through silicon via (TSV) processing. The vertical coil spacing distance 2434 and the lateral spacing distance D between the second coil 2427 and the first terminal 2425 can be adjusted to accommodate a desired isolation level for a given design.

Described examples and variants thereof can be used to provide voltage isolation with signal and/or power transfer between different voltage domains in a compact package using operatively coupled coils of stacked dies, for example, low voltage and high voltage power/signal transfer, receive and transmit signal transfer, etc. Various stacked arrangements can be used such as face to face (FIGS. 1, 21, 23 and 24), face up (FIG. 22) with interconnections by bond wires (e.g., FIGS. 1, 21, 22 and 24) and/or flip chip soldering/attachment (FIGS. 23 and 24). In face to face stacked configurations, the dielectric layers of the dies (e.g., SiO2 or other passivation protective overcoat (PO) layer) contribute to dielectric for a desired amount of voltage isolation. Described examples provide inductive isolation, where the die placement tolerance from standard pick and place equipment can be used without any performance degradation and provides robust power transfer and signal isolation. Different assembly approaches can be used for attaching the stacked dies, including die to die attachment (individual die stacking), chip to wafer (C2W) die stacking, wafer to wafer attachment, or other approaches. In any stacking approach, no custom lead frame design is needed and low cost (e.g., stamped) lead frames or single or multilevel substrates can be used. Various implementations have specific benefits and advantages, for example, where chip to wafer stacking (e.g., method 200 in FIG. 2) the die stacking is decoupled from the packaging or assembly processing and can mitigate or avoid costs associated with multi-chip modules (MCM). Some examples can use any suitable electrical coupling for interconnections, such as back side etching to reveal wire bond pads, using a through silicon via (TSV) to provide an interconnect, etc.

Modifications are possible in the described examples, and other implementations are possible, within the scope of the claims.

What is claimed is:

1. An electronic device, comprising:
a first semiconductor die, having a first terminal and a first metallization structure with a first coil; and
a second semiconductor die, having opposite first and second sides, a second terminal, a second coil in a second metallization structure, and a dielectric layer on the second side of the second semiconductor die, the first semiconductor die attached to the dielectric layer of the second semiconductor die, and the second coil aligned to the first coil.

2. The electronic device of claim 1, wherein the second terminal of the second semiconductor die is exposed through an opening in the dielectric layer of the second semiconductor die.

3. The electronic device of claim 2, wherein:
a first bond wire is coupled to the first terminal;
the first terminal of the first semiconductor die is a first bond pad or a first via exposed along a first side of the first semiconductor die;
an opposite second side of the first semiconductor die is attached to the second side of the second semiconductor die;
a second bond wire is coupled to the second terminal; and
the second terminal of the second semiconductor die is a second bond pad.

4. The electronic device of claim 1, wherein:
the first terminal of the first semiconductor die is a first metal pillar coupled to a substrate; and
the second terminal of the second semiconductor die is a second metal pillar coupled to the substrate.

5. The electronic device of claim 1, wherein the first semiconductor die is attached to the dielectric layer of the second semiconductor die by a non-conductive adhesive.

6. The electronic device of claim 1, wherein:
the first semiconductor die has opposite first and second sides;
the first semiconductor die has a first dielectric layer on the first metallization structure on the second side of the first semiconductor die;
the dielectric layer of the second semiconductor die is a second dielectric layer; and
the second side of the first semiconductor die is attached to and faces the second side of the second semiconductor die.

7. The electronic device of claim 6, wherein:
the first coil includes metal features of an uppermost layer of the first metallization structure that is closest to the second semiconductor die;
the first terminal includes a metal feature in a lowest layer of the first metallization structure that is farthest from the second semiconductor die; and
the first terminal is contacted by a first bond wire through a trench that extends into the first side of the first semiconductor die.

8. The electronic device of claim 6, wherein the first terminal of the first semiconductor die is contacted by a metal via in a trench that extends into the first side of the first semiconductor die.

9. The electronic device of claim 6, wherein the first terminal of the first semiconductor die is contacted by a first metal pillar that is coupled to a substrate or to the second semiconductor die.

10. The electronic device of claim 1, wherein:
the first semiconductor die has opposite first and second sides;
the first semiconductor die has a first dielectric layer on the first metallization structure on the second side of the first semiconductor die;
the dielectric layer of the second semiconductor die is a second dielectric layer; and
the first side of the first semiconductor die is attached to and faces the second side of the second semiconductor die.

11. The electronic device of claim 10, wherein:
the first coil includes metal features of a lowest layer of the first metallization structure that is closest to the second semiconductor die;
the first terminal includes a metal feature in an uppermost layer of the first metallization structure that is farthest from the second semiconductor die; and
the first terminal is contacted by a first bond wire through an opening in the first dielectric layer of the first semiconductor die.

12. The electronic device of claim 1, wherein the first semiconductor die is flip chip attached to the second semiconductor die.

13. A system, comprising:
a circuit board having first and second conductive features; and
an electronic device having first and second semiconductor dies, the first semiconductor die having a first terminal coupled to the first conductive feature of the circuit board, and a first metallization structure with a first coil, the second semiconductor die having opposite first and second sides, a second terminal coupled to the second conductive feature of the circuit board, a second coil in a second metallization structure, and a dielectric layer on the second side of the second semiconductor die, the first semiconductor die attached to the dielectric layer of the second semiconductor die, and the second coil aligned to the first coil.

14. The system of claim 13, wherein the second terminal of the second semiconductor die is exposed through an opening in the dielectric layer of the second semiconductor die.

15. The system of claim 13, wherein:
a first bond wire is coupled to the first terminal;
the first terminal of the first semiconductor die is a first bond pad or a first via exposed along a first side of the first semiconductor die;
an opposite second side of the first semiconductor die is attached to the second side of the second semiconductor die;
a second bond wire is coupled to the second terminal; and
the second terminal of the second semiconductor die is a second bond pad.

16. The system of claim 13, wherein the first semiconductor die is attached to the dielectric layer of the second semiconductor die by a non-conductive adhesive.

17. The system of claim 13, wherein:
the first semiconductor die has opposite first and second sides;
the first semiconductor die has a first dielectric layer on the first metallization structure on the second side of the first semiconductor die;
the dielectric layer of the second semiconductor die is a second dielectric layer; and
the second side of the first semiconductor die is attached to and faces the second side of the second semiconductor die.

18. A method of fabricating an electronic device, the method comprising:
attaching a first semiconductor die to a second side of a second semiconductor die with a first coil of the first semiconductor die aligned with a second coil of the second semiconductor die;
attaching an opposite first side of the second semiconductor die to a lead frame;
electrically coupling a first terminal of the first semiconductor die to a first lead of the lead frame; and
electrically coupling a second terminal of the second semiconductor die to a second lead of the lead frame.

19. The method of claim 18, wherein:
the first semiconductor die has opposite first and second sides;
the first semiconductor die has a first dielectric layer on a first metallization structure on the second side of the first semiconductor die;
the second semiconductor die has a second dielectric layer on a second metallization structure on the second side of the second semiconductor die; and
attaching the first semiconductor die to the second side of the second semiconductor die includes attaching the second side of the first semiconductor die to the second side of the second semiconductor die using a non-conductive adhesive.

20. The method of claim 19, wherein electrically coupling the first terminal of the first semiconductor die to the first lead of the lead frame includes:
forming a trench that extends into the second side of the first semiconductor die to expose the first terminal; and
forming a bond wire connection to the first terminal through the trench.

21. The method of claim 19, wherein electrically coupling the first terminal of the first semiconductor die to the first lead of the lead frame includes:
forming a trench that extends into the second side of the first semiconductor die to expose the first terminal;
forming a metal via in the trench; and
forming a bond wire connection to the metal via.

22. The method of claim 18, wherein attaching the first semiconductor die to the second side of the second semiconductor die includes flip chip attaching the first semiconductor die to the second semiconductor die.
